(19) United States
(12) Patent Application Publication
(10) Pub. No.: US 2018/0052732 A1
(43) Pub. Date: Feb. 22, 2018

(54) SEMICONDUCTOR DEVICE AND SEMICONDUCTOR SYSTEM

(71) Applicant: SK hynix Inc., Icheon-si Gyeonggi-do (KR)

(72) Inventors: Sang Gu JO, Bucheon-si Gyeonggi-do (KR); Jung Hyun KWON, Seoul (KR); Donggun KIM, Hwaseong-si Gyeonggi-do (KR); Yong Ju KIM, Seoul (KR); Sungeun LEE, Icheon-si Gyeonggi-do (KR); Jae Sun LEE, Seoul (KR); JINGZHE XU, Seoul (KR); Do-Sun HONG, Icheon-si Gyeonggi-do (KR)

(73) Assignee: SK hynix Inc., Icheon-si Gyeonggi-do (KR)

(21) Appl. No.: 15/469,047

(22) Filed: Mar. 24, 2017

(30) Foreign Application Priority Data
Aug. 16, 2016 (KR) 1020160103494

(51) Int. Cl. G06F 11/10; G11C 29/52

(52) U.S. Cl. CPC G06F 11/1068; G11C 29/52

(57) ABSTRACT

A semiconductor system may be provided. The semiconductor system may include a first semiconductor device configured for outputting a transmission command and a transmission address, being inputted with and outputting transmission data, and generating an error flag signal when an error bit is included in the transmission data inputted in a read operation. The semiconductor system may include a second semiconductor device configured for storing the transmission address in a lookup table circuit when the error flag signal is enabled, and comparing the transmission address and a storage address stored in the lookup table circuit when the read operation is performed based on the transmission command and outputting the transmission data from the lookup table circuit.

### CROSS-REFERENCE TO RELATED APPLICATION

The present application claims priority under 35 U.S.C. § 119(a) to Korean Patent Application No. 10-2016-0103494 filed on Aug. 16, 2016 in the Korean Intellectual Property Office, which is incorporated herein by reference in its entirety.

### BACKGROUND

### 1. Technical Field

Embodiments of the present disclosure may generally relate to a semiconductor system, and more particularly, to a semiconductor system including a semiconductor device relating to the performance of an error correction operation.

### 2. Related Art

Recently, in order to increase the operating speed of a semiconductor device, DDR2 or DDR3 signaling is used, in which 4-bit or 8-bit data are inputted and outputted (inputted/outputted) in each clock cycle. In the case where an input/output speed of data is increased, the probability of an error occurring during a data transmission process increases. Therefore, a separate device and method for ensuring the reliability of data transmissions are additionally demanded.

There is disclosed a method of generating, at each time of transmitting data, error codes capable of checking for an occurrence of an error and transmitting the error codes with data, thereby ensuring the reliability of a data transmission. The error codes include an error detection code (EDC) capable of detecting an error occurred and an error correction code (ECC) capable of correcting, by itself, an error when it has occurred.

### SUMMARY

In an embodiment, a semiconductor system may be provided. The semiconductor system may include a first semiconductor device configured for outputting a transmission command and a transmission address, being inputted with and outputting transmission data, and generating an error flag signal when an error bit is included in the transmission data inputted in a read operation. The semiconductor system may include a second semiconductor device configured for storing the transmission address in a lookup table circuit when the error flag signal is enabled, and comparing the transmission address and a storage address stored in the lookup table circuit when the read operation is performed based on the transmission command and outputting the transmission data from the lookup table circuit.

In an embodiment, a semiconductor device may be provided the semiconductor device may include a lookup table circuit configured for generating a control signal which has a first logic level when an internal address and a storage address stored therein are the same in a read operation, outputting first storage data stored therein, based on the control signal, and storing the internal address based on an error flag signal. The semiconductor device may include a path selection circuit configured for transferring the first storage data as first internal data when the control signal has the first logic level. The semiconductor device may include an error correction circuit configured for outputting second internal data by correcting an error of the first internal data, and generating the error flag signal when the error of the first internal data occurs.

In an embodiment, a semiconductor system may be provided. The semiconductor system may include a first semiconductor device configured for outputting a transmission command and a transmission address based on a control signal which is generated by comparing a host address and a storage address stored in a lookup table circuit when a read operation is performed, transferring transmission data or storage data outputted from the lookup table circuit, as internal data, based on the control signal, and storing the host address in the lookup table circuit when the internal data includes an error bit. The semiconductor system may include a second semiconductor device configured for storing or outputting the transmission data based on the transmission command and the transmission address.

In an embodiment, a semiconductor system may be provided. The semiconductor system may include a first semiconductor device configured for detecting an error in transmission data and generating a transmission address. The semiconductor system may include a second semiconductor device configured to receive the transmission address from the first semiconductor device, compare the transmission address and a storage address stored in a lookup table circuit and output the transmission data from the lookup table circuit or a memory core circuit based on the comparison.

### BRIEF DESCRIPTION OF THE DRAWINGS

FIG. 1 is a block diagram illustrating a representation of an example of the configuration of a semiconductor system in accordance with an embodiment.

FIG. 2 is a block diagram illustrating a representation of an example of the lookup table circuit included in the semiconductor system illustrated in FIG. 1.

FIG. 3 is a block diagram illustrating a representation of an example of the configuration of a semiconductor system in accordance with an embodiment.

FIG. 4 is a block diagram illustrating a representation of an example of the configuration of a semiconductor system in accordance with an embodiment.

FIG. 5 is a diagram illustrating a representation of an example of the configuration of an electronic system to which the semiconductor device and the semiconductor system illustrated in FIGS. 1 to 4 are applied.

FIG. 6 is a diagram illustrating a representation of an example of the configuration of an electronic system to which the semiconductor device and the semiconductor system illustrated in FIGS. 1 to 4 are applied.

### DETAILED DESCRIPTION

Hereinafter, a semiconductor device and a semiconductor system will be described below with reference to the accompanying drawings through various examples of embodiments.

Various embodiments may be directed to a semiconductor system including a semiconductor device which stores, in the case where an error bit is included in data in a read operation, an address including the information of a position where the data is stored, in a lookup table circuit.

various embodiments may be directed to a semiconductor system including a semiconductor device which stores or outputs data through a lookup table circuit in the case where an error bit is included in data in a read operation or a write operation for a memory core circuit according to an address.

According to some of the embodiments, in the case where an error bit is included in data in a read operation, a lookup table circuit stores an address including the information of a position where the data is stored, whereby it may be possible to easily manage a bad address.

Also, according to some of the embodiments, data is stored or outputted through a lookup table circuit in the case where an error bit is included in data in a read operation or a write operation for a memory core circuit according to an address, whereby it may be possible to suppress an occurrence of an error in data.

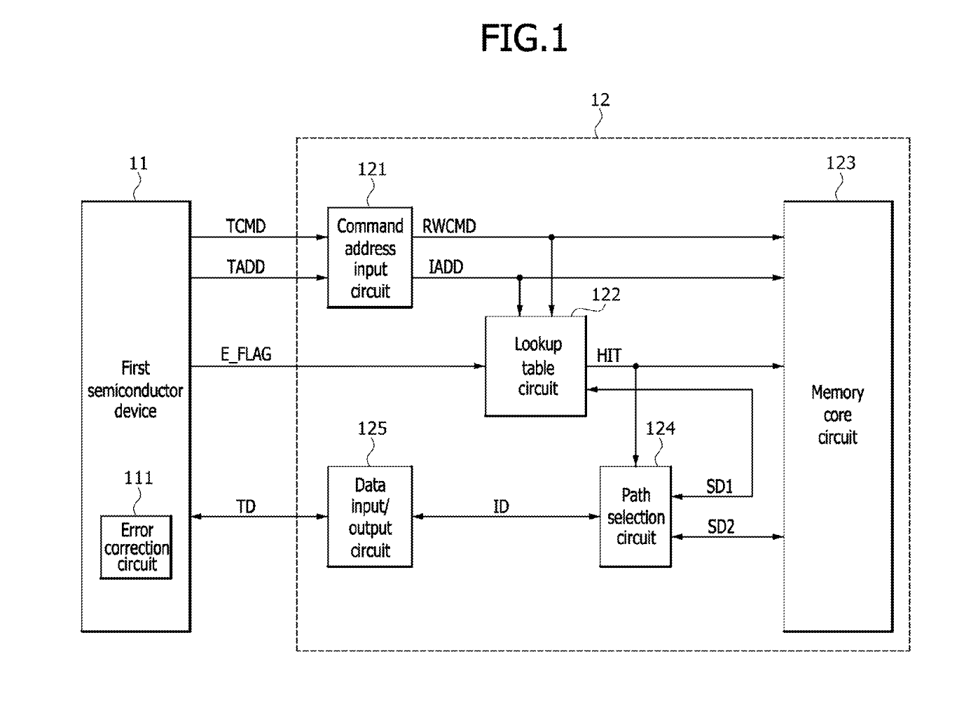

Referring to FIG. 1, a semiconductor system in accordance with an embodiment may include a first semiconductor device 11 and a second semiconductor device 12.

The first semiconductor device 11 may output a transmission command TCMD, a transmission address TADD and an error flag signal E_FLAG, and may be inputted with and outputted with transmission data TD. The transmission command TCMD may be realized by a plurality of bits, and have logic level combinations corresponding to a read operation and a write operation for the second semiconductor device 12. The transmission address TADD may be realized by a plurality of bits, and have logic level combinations for selecting the memory cells (not illustrated) included in the second semiconductor device 12. The transmission command TCMD and the transmission address TADD may be transmitted through the same transmission line. The first semiconductor device 11 may be inputted with the transmission data TD in the read operation. The first semiconductor device 11 may output the transmission data TD in the write operation. The transmission data TD may include parity for correcting an error bit included in the transmission data TD. The first semiconductor device 11 may be a controller which controls the second semiconductor device 12. The first semiconductor device 11 may include an error correction circuit 111. The error correction circuit 111 may perform an error correction operation of correcting an error of the transmission data TD in the read operation. The transmission data TD may include data and parity. The parity may be an error correction code (ECC) for correcting an error of data. The error correction circuit 111 may generate the error flag signal E_FLAG which is enabled in the case where an error bit is included in the transmission data TD in the read operation. According to an embodiment, the error correction circuit 111 may generate the error flag signal E_FLAG which is enabled in the case where the number of error bits included in the transmission data TD exceeds an error correction range. The error correction circuit 111 may generate the error flag signal E_FLAG which is enabled in the case where the number of error bits included in the transmission data TD is equal to or larger than a predetermined number. In the case where the write operation is performed, the error correction circuit 111 may be inputted with data from a host (not illustrated) and generate parity, and generate the transmission data TD including the data and the parity.

The second semiconductor device 12 may include a command address input circuit 121, a lookup table circuit 122, a memory core circuit 123, a path selection circuit 124, and a data input/output circuit 125.

The command address input circuit 121 may generate a read write command RWCMD and an internal address IADD from the transmission command TCMD and the transmission address TADD. The command address input circuit 121 may generate the read write command RWCMD by decoding the transmission command TCMD. The read write command RWCMD may include a bit which is enabled in the read operation and a bit which is enabled in the write operation. The command address input circuit 121 may generate the internal address IADD by buffering the transmission address TADD.

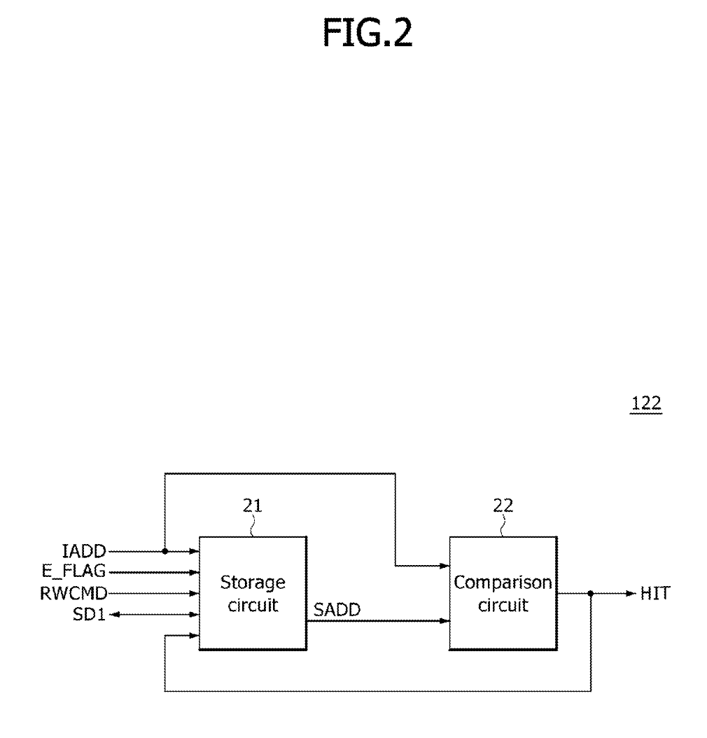

The lookup table circuit 122 may compare the internal address IADD and a storage address SADD (see FIG. 2) stored therein, in response to the read write command RWCMD, and generate a control signal HIT. The lookup table circuit 122 may generate the control signal HIT which has a first logic level, in the case where the internal address IADD and the storage address SADD are the same. The lookup table circuit 122 may generate the control signal HIT which has a second logic level, in the case where the internal address IADD and the storage address SADD are not the same. The lookup table circuit 122 may store a plurality of storage addresses SADD. In the case where the plurality of storage addresses SADD are stored in the lookup table circuit 122, the lookup table circuit 122 may generate the control signal HIT by sequentially comparing the internal address IADD and the plurality of storage addresses SADD. The lookup table circuit 122 may output first storage data SD1 in the case where the control signal HIT is the first logic level in the read operation. The lookup table circuit 122 may output the first storage data SD1 stored at a position corresponding to the storage address SADD in the case where the control signal HIT is the first logic level in the read operation. The lookup table circuit 122 may store first storage data SD1 in the case where the control signal HIT is the first logic level in the write operation. The lookup table circuit 122 may store the first storage data SD1 at a position corresponding to the storage address SADD in the case where the control signal HIT is the first logic level in the write operation. The first storage data SD1 may include data and parity. The lookup table circuit 122 may include a storage region which stores data and a storage region which stores parity. The lookup table circuit 122 may store the internal address IADD in response to the error flag signal E_FLAG. The lookup table circuit 122 may store the internal address IADD in the case where the error flag signal E_FLAG is enabled. The lookup table circuit 122 may include a storage region which stores the internal address IADD.

The memory core circuit 123 may store or output second storage data SD2 in response to the read write command RWCMD, the internal address IADD and the control signal HIT. The memory core circuit 123 may output the second storage data SD2 stored at a position corresponding to the internal address IADD in the case where the read operation is performed in response to the read write command RWCMD and the control signal HIT is the second logic level. The memory core circuit 123 may block output of the second storage data SD2 in the case where the read operation is performed in response to the read write command RWCMD and the control signal HIT is the first logic level. The memory core circuit 123 may store the second storage data SD2 at a position corresponding to the internal address IADD in the case where the write operation is performed in response to the read write command RWCMD and the control signal HIT is the second logic level. The memory core circuit 123 may block input of the second storage data SD2 in the case where the write operation is performed in response to the read write command RWCMD and the control signal HIT is the first logic level. The second storage data SD2 may include data and parity. The memory core circuit 123 may include a storage region which stores data and a storage region which stores parity.

The path selection circuit 124 may transfer the first storage data SD1 or the second storage data SD2 as internal data ID in response to the control signal HIT. The path selection circuit 124 may transfer internal data ID as the first storage data SD1 or the second storage data SD2 in response to the control signal HIT. The path selection circuit 124 may transfer the first storage data SD1 as the internal data ID in the case where the control signal HIT has the first logic level in the read operation. The path selection circuit 124 may transfer the second storage data SD2 as the internal data ID in the case where the control signal HIT is the second logic level in the read operation. The path selection circuit 124 may transfer the internal data ID as the first storage data SD1 in the case where the control signal HIT has the first logic level in the write operation. The path selection circuit 124 may transfer the internal data ID as the second storage data SD2 in the case where the control signal HIT is the second logic level in the write operation.

The data input/output circuit 125 may buffer the internal data ID and output the transmission data TD, or buffer the transmission data TD and output the internal data ID. The data input/output circuit 125 may buffer the internal data ID and output the transmission data TD in the read operation. The data input/output circuit 125 may buffer the transmission data TD and output the internal data ID in the write operation.

Referring to FIG. 2, the lookup table circuit 122 may include a storage circuit 21 and a comparison circuit 22.

The storage circuit 21 may output the storage address SADD in response to the read write command RWCMD. The storage circuit 21 may output the first storage data SD1 in response to the control signal HIT in the case where the read operation is performed in response to the read write command RWCMD. The storage circuit 21 may output the first storage data SD1 stored at the position corresponding to the storage address SADD in the case where the control signal HIT is the first logic level in the read operation. The storage circuit 21 may store the first storage data SD1 in response to the control signal HIT in the case where the write operation is performed in response to the read write command RWCMD. The storage circuit 21 may store the first storage data SD1 at the position corresponding to the storage address SADD in the case where the control signal HIT is the first logic level in the write operation. The first storage data SD1 may include data and parity. The storage circuit 21 may include a storage region which stores data and a storage region which stores parity. The storage circuit 21 may store the internal address IADD in response to the error flag signal E_FLAG. The storage circuit 21 may store the internal address IADD as the storage address SADD in the case where the error flag signal E_FLAG is enabled.

The comparison circuit 22 may compare the internal address IADD and the storage address SADD and generate the control signal HIT. The comparison circuit 22 may generate the control signal HIT which has the first logic level, in the case where the internal address IADD and the storage address SADD are the same. The comparison circuit 22 may generate the control signal HIT which has the second logic level, in the case where the internal address IADD and the storage address SADD are not the same.

Descriptions will be made by providing an example of a case where an error bit occurs in the second storage data SD2 outputted from the memory core circuit 123 in the semiconductor system in accordance with an embodiment.

The first semiconductor device 11 may output the transmission command TCMD and the transmission address TADD corresponding to the read operation. The second semiconductor device 12 may generate the read write command RWCMD and the internal address IADD from the transmission command TCMD and the transmission address TADD. The lookup table circuit 122 may compare the internal address IADD and the storage address SADD stored therein, and generate the control signal HIT of the second logic level in the case where the internal address IADD and the storage address SADD are not the same. The memory core circuit 123 may output the data and parity of a memory cell corresponding to the internal address IADD, as the second storage data SD2, in response to the control signal HIT of the second logic level. The path selection circuit 124 may output the second storage data SD2 as the internal data ID in response to the control signal HIT of the second logic level. The data input/output circuit 125 may output the internal data ID as the transmission data TD. The first semiconductor device 11 may perform the error correction operation of correcting an error of the transmission data TD by the error correction circuit 111. The first semiconductor device 11 may generate the error flag signal E_FLAG which is enabled in the case where an error bit is included in the transmission data TD. The lookup table circuit 122 included in the second semiconductor device 12 may store the internal address IADD in the case where the error flag signal E_FLAG is enabled.

Thereafter, in the case where a read or write operation is performed in correspondence to the transmission address TADD in the case where the error bit occurs in the second storage data SD2, the second semiconductor device 12 may generate the control signal HIT by comparing the transmission address TADD inputted to the second semiconductor device 12 and the storage address SADD, and, in response to the control signal HIT, may output the data and parity outputted from the lookup table circuit 122, as the transmission data TD, or store the data and parity inputted as the transmission data TD, in the lookup table circuit 122.

As is apparent from the above descriptions, in the semiconductor system in accordance with an embodiment, in the case where an error occurs in the memory core circuit 123 and thus an error bit is included in the internal data ID, the internal address IADD including the information of a position where the internal data ID is stored may be stored in the lookup table circuit 122. In the case where a read operation or a write operation is performed for the storage address SADD stored in the lookup table circuit 122, data may be outputted or stored through the lookup table circuit 122, whereby it may be possible to substantially suppress occurrence of an error in data.

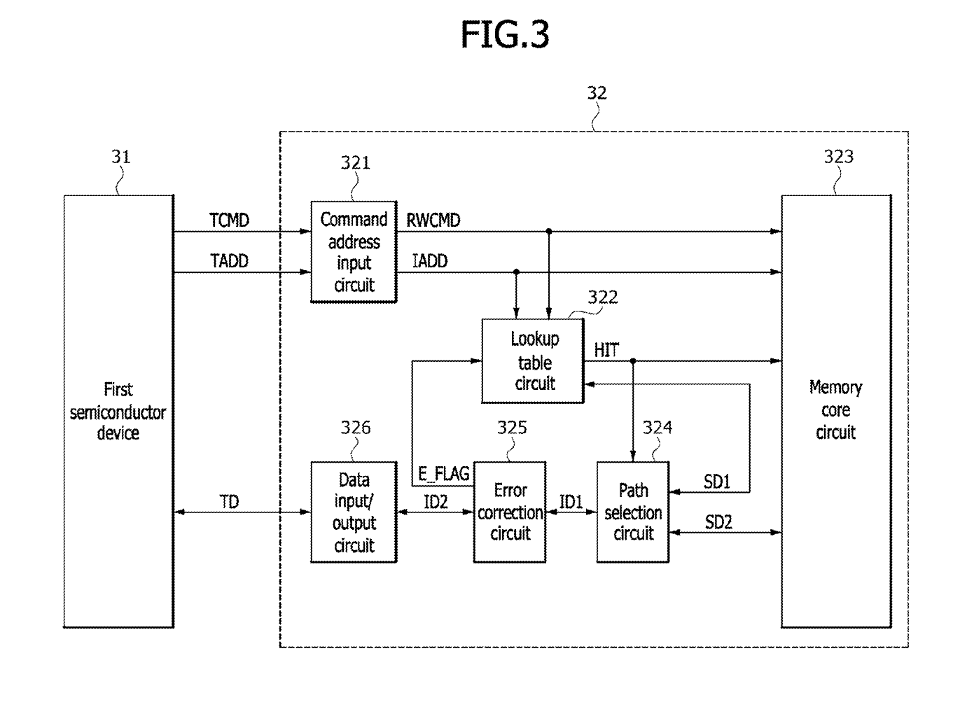

Referring to FIG. 3, a semiconductor system in accordance with another embodiment may include a first semiconductor device 31 and a second semiconductor device 32.

The first semiconductor device 31 may output a transmission command TCMD and a transmission address TADD, and be inputted with and output transmission data TD. The transmission command TCMD may be realized by a plurality of bits, and have logic level combinations corresponding to a read operation and a write operation for the second semiconductor device 32. The transmission address TADD may be realized by a plurality of bits, and have logic level combinations for selecting the memory cells (not illustrated) included in the second semiconductor device 32. The transmission command TCMD and the transmission address TADD may be transmitted through the same transmission line. The first semiconductor device 31 may be inputted with the transmission data TD in the read operation. The first semiconductor device 31 may output the transmission data TD in the write operation. The transmission data TD may include parity for correcting an error bit included in the transmission data TD. The first semiconductor device 31 may be a controller which controls the second semiconductor device 32.

The second semiconductor device 32 may include a command address input circuit 321, a lookup table circuit 322, a memory core circuit 323, a path selection circuit 324, an error correction circuit 325, and a data input/output circuit 326.

The command address input circuit 321 may generate a read write command RWCMD and an internal address IADD from the transmission command TCMD and the transmission address TADD. The command address input circuit 321 may generate the read write command RWCMD by decoding the transmission command TCMD. The read write command RWCMD may include a bit which is enabled in the read operation and a bit which is enabled in the write operation. The command address input circuit 321 may generate the internal address IADD by buffering the transmission address TADD.

The lookup table circuit 322 may compare the internal address IADD and a storage address SADD (see FIG. 2) stored therein, in response to the read write command RWCMD, and generate a control signal HIT. The lookup table circuit 322 may generate the control signal HIT which has a first logic level, in the case where the internal address IADD and the storage address SADD are the same. The lookup table circuit 322 may generate the control signal HIT which has a second logic level, in the case where the internal address IADD and the storage address SADD are not the same. The lookup table circuit 322 may store a plurality of storage addresses SADD. In the case where the plurality of storage addresses SADD are stored in the lookup table circuit 322, the lookup table circuit 322 may generate the control signal HIT by sequentially comparing the internal address IADD and the plurality of storage addresses SADD. The lookup table circuit 322 may output first storage data SD1 in the case where the control signal HIT is the first logic level in the read operation. The lookup table circuit 322 may output the first storage data SD1 stored at a position corresponding to the storage address SADD in the case where the control signal HIT is the first logic level in the read operation. The lookup table circuit 322 may store first storage data SD1 in the case where the control signal HIT is the first logic level in the write operation. The lookup table circuit 322 may store the first storage data SD1 at the position corresponding to the storage address SADD in the case where the control signal HIT is the first logic level in the write operation. The first storage data SD1 may include data and parity. The lookup table circuit 322 may include a storage region which stores data and a storage region which stores parity. The lookup table circuit 322 may store the internal address IADD in response to an error flag signal E_FLAG. The lookup table circuit 322 may store the internal address IADD in the case where the error flag signal E_FLAG is enabled. The lookup table circuit 322 may include a storage region which stores the internal address IADD. The lookup table circuit 322 may have the same configuration as the lookup table circuit 122 illustrated in FIG. 2.

The memory core circuit 323 may store or output second storage data SD2 in response to the read write command RWCMD, the internal address IADD and the control signal HIT. The memory core circuit 323 may output the second storage data SD2 stored at a position corresponding to the internal address IADD in the case where the read operation is performed in response to the read write command RWCMD and the control signal HIT is the second logic level. The memory core circuit 323 may block output of the second storage data SD2 stored at the position corresponding to the internal address IADD in the case where the read operation is performed in response to the read write command RWCMD and the control signal HIT is the first logic level. The memory core circuit 323 may store the second storage data SD2 at a position corresponding to the internal address IADD in the case where the write operation is performed in response to the read write command RWCMD and the control signal HIT is the second logic level. The memory core circuit 323 may block input of the second storage data SD2 to the position corresponding to the internal address IADD in the case where the write operation is performed in response to the read write command RWCMD and the control signal HIT is the first logic level. The second storage data SD2 may include data and parity. The memory core circuit 323 may include a storage region which stores data and a storage region which stores parity.

The path selection circuit 324 may transfer the first storage data SD1 or the second storage data SD2 as first internal data ID1 in response to the control signal HIT. The path selection circuit 324 may transfer first internal data ID1 as the first storage data SD1 or the second storage data SD2 in response to the control signal HIT. The path selection circuit 324 may transfer the first storage data SD1 as the first internal data ID1 in the case where the control signal HIT has the first logic level in the read operation. The path selection circuit 324 may transfer the second storage data SD2 as the first internal data ID1 in the case where the control signal HIT is the second logic level in the read operation. The path selection circuit 324 may transfer the first internal data ID1 as the first storage data SD1 in the case where the control signal HIT has the first logic level in the write operation. The path selection circuit 324 may transfer the first internal data ID1 as the second storage data SD2 in the case where the control signal HIT is the second logic level in the write operation.

The error correction circuit 325 may perform an error correction operation of correcting an error of the first internal data ID1 in the read operation and outputting second internal data ID2. The first internal data ID1 may include data and parity. The parity may be an error correction code (ECC) for correcting an error of data. The error correction circuit 325 may generate the error flag signal E_FLAG which is enabled in the case where an error bit is included in the first internal data ID1 in the read operation. According to an embodiment, the error correction circuit 325 may generate the error flag signal E_FLAG which is enabled in the case where the number of error bits included in the first internal data ID1 exceeds an error correction range. The error correction circuit 325 may generate the error flag signal E_FLAG which is enabled in the case where the number of error bits included in the first internal data ID1 is equal to or larger than a predetermined number. In the case where the write operation is performed, the error correction circuit 325 may be inputted with second internal data ID2 from the data input/output circuit 326 and generate parity, and generate the first internal data ID1 including the data and the parity.

The data input/output circuit 326 may buffer the second internal data ID2 and output the transmission data TD, or buffer the transmission data TD and output the second internal data ID2. The data input/output circuit 326 may buffer the second internal data ID2 and output the transmission data TD in the read operation. The data input/output circuit 326 may buffer the transmission data TD and output the second internal data ID2 in the write operation.

As is apparent from the above descriptions, in the semiconductor system illustrated in FIG. 3, the error correction circuit 325 is included in the second semiconductor device 32 which includes the memory core circuit 323. Therefore, in the case where an error bit is included in the first internal data ID1, the second semiconductor device 32 may internally store the internal address IADD and the first storage data SD1 in the lookup table circuit 322.

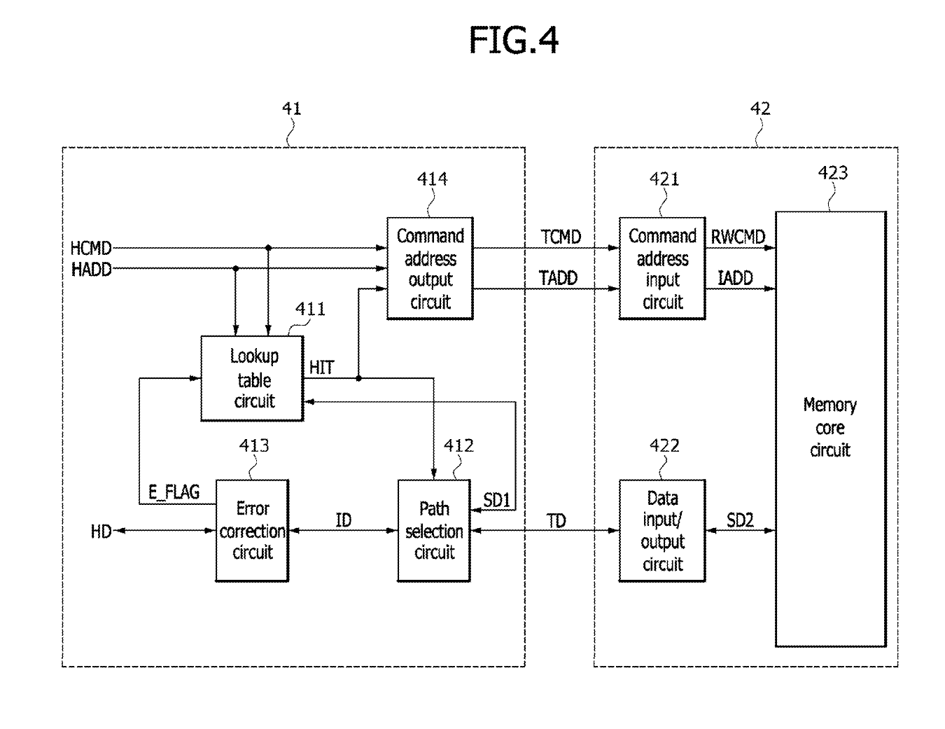

Referring to FIG. 4, a semiconductor system in accordance with an embodiment may include a first semiconductor device 41 and a second semiconductor device 42.

The first semiconductor device 41 may include a lookup table circuit 411, a path selection circuit 412, an error correction circuit 413, and a command address output circuit 414.

The lookup table circuit 411 may compare a host address HADD and a storage address SADD (see FIG. 2) stored therein, in response to a host command HCMD, and generate a control signal HIT. The lookup table circuit 411 may generate the control signal HIT which has a first logic level, in the case where the host address HADD and the storage address SADD are the same. The lookup table circuit 411 may generate the control signal HIT which has a second logic level, in the case where the host address HADD and the storage address SADD are not the same. The lookup table circuit 411 may store a plurality of storage addresses SADD. In the case where the plurality of storage addresses SADD are stored in the lookup table circuit 411, the lookup table circuit 411 may generate the control signal HIT by sequentially comparing the host address HADD and the plurality of storage addresses SADD. The lookup table circuit 411 may output first storage data SD1 in the case where the control signal HIT is the first logic level in a read operation. The lookup table circuit 411 may output the first storage data SD1 stored at a position corresponding to the storage address SADD in the case where the control signal HIT is the first logic level in the read operation. The lookup table circuit 411 may store first storage data SD1 in the case where the control signal HIT is the first logic level in a write operation. The lookup table circuit 411 may store the first storage data SD1 at the position corresponding to the storage address SADD in the case where the control signal HIT is the first logic level in the write operation. The first storage data SD1 may include data and parity. The lookup table circuit 411 may include a storage region which stores data and a storage region which stores parity. The lookup table circuit 411 may store the host address HADD in response to an error flag signal E_FLAG. The lookup table circuit 411 may store the host address HADD in the case where the error flag signal E_FLAG is enabled. The lookup table circuit 411 may include a storage region which stores the host address HADD. The lookup table circuit 411 may have substantially the same configuration as the lookup table circuit 122 illustrated in FIG. 2, except for the signals inputted and outputted therein. The host command HCMD and the host address HADD may be inputted from a host device (not illustrated).

The path selection circuit 412 may transfer the first storage data SD1 or transmission data TD as internal data ID in response to the control signal HIT. The path selection circuit 412 may transfer internal data ID as the first storage data SD1 or transmission data TD in response to the control signal HIT. The path selection circuit 412 may transfer the first storage data SD1 as the internal data ID in the case where the control signal HIT has the first logic level in the read operation. The path selection circuit 412 may transfer the transmission data TD as the internal data ID in the case where the control signal HIT is the second logic level in the read operation. The path selection circuit 412 may transfer the internal data ID as the first storage data SD1 in the case where the control signal HIT has the first logic level in the write operation. The path selection circuit 412 may transfer the internal data ID as the transmission data TD in the case where the control signal HIT is the second logic level in the write operation.

The error correction circuit 413 may perform an error correction operation of correcting an error of the internal data ID in the read operation and outputting host data HD. The internal data ID may include data and parity. The parity may be an error correction code (ECC) for correcting an error of data. The error correction circuit 413 may generate the error flag signal E_FLAG which is enabled in the case where an error bit is included in the internal data ID in the read operation. According to an embodiment, the error correction circuit 413 may generate the error flag signal E_FLAG which is enabled in the case where the number of error bits included in the internal data ID exceeds an error correction range. The error correction circuit 413 may generate the error flag signal E_FLAG which is enabled in the case where the number of error bits included in the internal data ID is equal to or larger than a predetermined number. In the case where the write operation is performed, the error correction circuit 413 may be inputted with host data HD from the host device and generate parity, and generate the internal data ID including the data and the parity.

The command address output circuit 414 may output the host command HCMD and the host address HADD as a transmission command TCMD and a transmission address TADD in response to the control signal HIT. The command address output circuit 414 may block output of the transmission command TCMD and the transmission address TADD in the case where the control signal HIT has the first logic level. The command address output circuit 414 may output the host command HCMD and the host address HADD as the transmission command TCMD and the transmission address TADD in the case where the control signal HIT has the second logic level. The transmission command TCMD and the transmission address TADD may be transmitted through the same transmission line.

The second semiconductor device 42 may include a command address input circuit 421, a data input/output circuit 422, and a memory core circuit 423.

The command address input circuit 421 may generate a read write command RWCMD and an internal address IADD from the transmission command TCMD and the transmission address TADD. The command address input circuit 421 may generate the read write command RWCMD by decoding the transmission command TCMD. The read write command RWCMD may include a bit which is enabled in the read operation and a bit which is enabled in the write operation. The command address input circuit 421 may generate the internal address IADD by buffering the transmission address TADD.

The data input/output circuit 422 may buffer second storage data SD2 and output the transmission data TD, or buffer the transmission data TD and output second storage data SD2. The data input/output circuit 422 may buffer the second storage data SD2 and output the transmission data TD in the read operation. The data input/output circuit 422 may buffer the transmission data TD and output the second storage data SD2 in the write operation.

The memory core circuit 423 may store or output the second storage data SD2 in response to the read write command RWCMD and the internal address IADD. The memory core circuit 423 may output the second storage data SD2 stored at a position corresponding to the internal address IADD in the case where the read operation is performed in response to the read write command RWCMD. The memory core circuit 423 may store the second storage data SD2 at a position corresponding to the internal address IADD in the case where the write operation is performed in response to the read write command RWCMD.

As is apparent from the above descriptions, in the semiconductor system illustrated in FIG. 4, the lookup table circuit 411 is included in the first semiconductor device 41. Therefore, in the case where an error occurs in the memory core circuit 423 and an error bit is included in the internal data ID, the host address HADD corresponding to the error bit may be stored in the lookup table circuit 411. In the case where a read operation or a write operation is performed for the storage address SADD stored in the lookup table circuit 411, data may be outputted or stored through the lookup table circuit 411, whereby an operation speed may be improved.

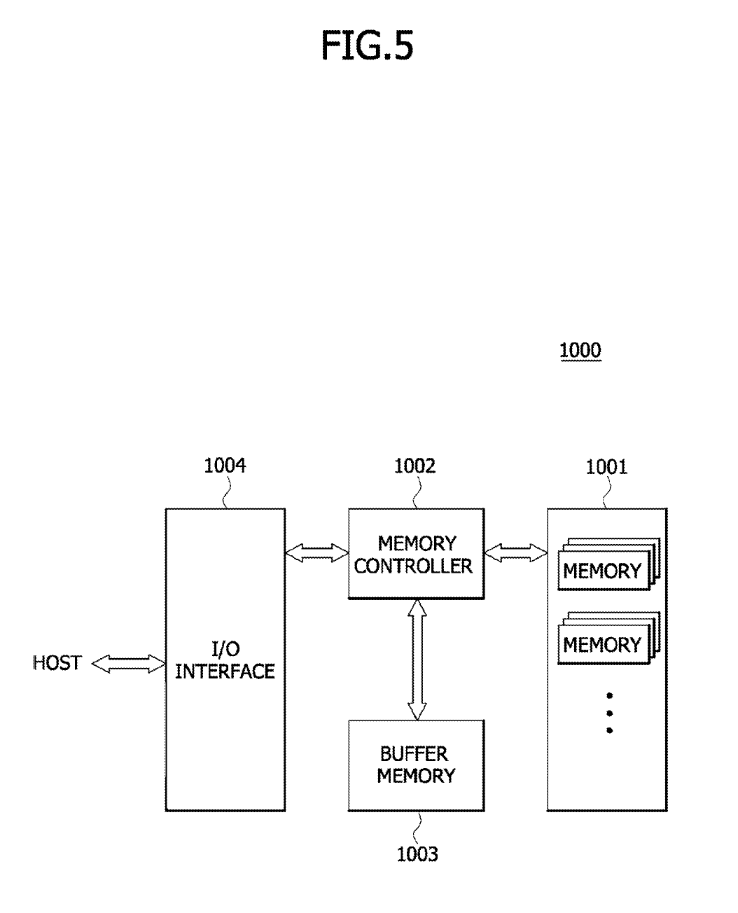

The semiconductor devices described above with reference to FIGS. 1 to 4 may be applied to an electronic system which includes a memory system, a graphic system, a computing system or a mobile system. For example, referring to FIG. 5, an electronic system 1000 in accordance with an embodiment may include a data storage 1001, a memory controller 1002, a buffer memory 1003, and an input/output interface 1004.

The data storage 1001 stores data applied from the memory controller 1002, and reads out stored data and outputs the read-out data to the memory controller 1002, according to control signals from the memory controller 1002. The data storage 1001 may include a second semiconductor device 12 illustrated in FIG. 1, a second semiconductor device 32 illustrated in FIG. 3 or a second semiconductor device 42 illustrated in FIG. 4. The data storage 1001 may include a nonvolatile memory capable of not losing and continuously storing data even though power supply is interrupted. A nonvolatile memory may be realized as a flash memory such as a NOR flash memory and a NAND flash memory, a phase change random access memory (PRAM), a resistive random access memory (RRAM), a spin transfer torque random access memory (STTRAM) or a magnetic random access memory (MRAM).

The memory controller 1002 decodes commands applied through the input/output interface 1004 from an external device (a host), and controls input/output of data with respect to the data storage 1001 and the buffer memory 1003 according to decoding results. The memory controller 1002 may include a first semiconductor device 11 illustrated in FIG. 1, the first semiconductor device 31 illustrated in FIG. 3 or the first semiconductor device 41 illustrated in FIG. 4. While the memory controller 1002 is illustrated as one block in FIG. 5, it is to be noted that, in the memory controller 1002, a controller for controlling a nonvolatile memory and a controller for controlling the buffer memory 1003 as a volatile memory may be independently configured.

The buffer memory 1003 may temporarily store data to be processed in the memory controller 1002, that is, data to be inputted and outputted to and from the data storage 1001. The buffer memory 1003 may store data applied from the memory controller 1002 according to a control signal. The buffer memory 1003 reads out stored data and outputs the read-out data to the memory controller 1002. The buffer memory 1003 may include a volatile memory such as a DRAM (dynamic random access memory), a mobile DRAM and an SRAM (static random access memory).

The input/output interface 1004 provides a physical coupling between the memory controller 1002 and the external device (the host) such that the memory controller 1002 may receive control signals for input/output of data from the external device and exchange data with the external device. The input/output interface 1004 may include one among various interface protocols such as USB, MMC, PCI-E, SAS, SATA, PATA, SCSI, ESDI and IDE.

The electronic system 1000 may be used as an auxiliary memory device or an external storage device of the host. The electronic system 1000 may include a solid state disk (SSD), a USB memory (universal serial bus memory), a secure digital (SD) card, a mini-secure digital (mSD) card, a micro SD card, a secure digital high capacity (SDHC) card, a memory stick card, a smart media (SM) card, a multimedia card (MMC), an embedded MMC (eMMC), or a compact flash (CF) card.

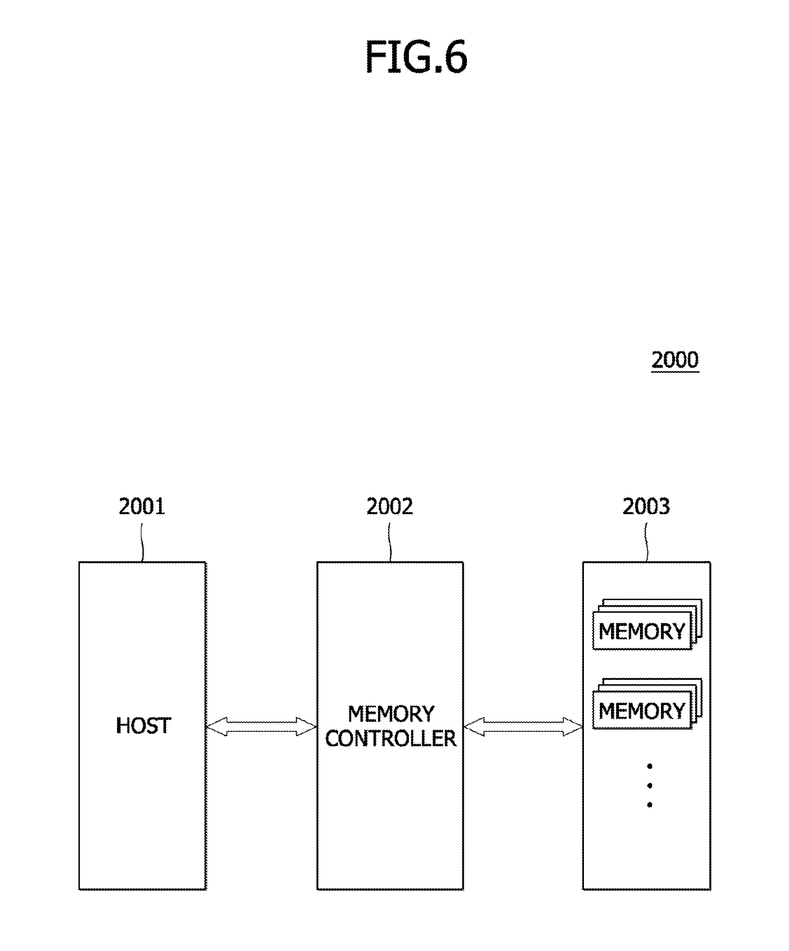

Referring to FIG. 6, an electronic system 2000 in accordance with an embodiment may include a host 2001, a memory controller 2002, and a data storage 2003.

The host 2001 may transmit a request and data to the memory controller 2002 to access the data storage 2003. The memory controller 2002 may provide data, a data strobe, a command, an address and a clock to the data storage 2003 in response to the request, and in response to this, the data storage 2003 may perform a write or read operation. The host 2001 may transmit data to the memory controller 2002 to store the data in the data storage 2003. Also, the host 2001 may receive, through the memory controller 2002, the data outputted from the data storage 2003. The host 2001 may include a circuit which corrects an error included in data, by using an error correction code (ECC) scheme.

The memory controller 2002 may relay communication between the host 2001 and the data storage 2003. The memory controller 2002 may receive a request and data from the host 2002. In order to control the operation of the data storage 2003, the memory controller 2002 may generate data, a data strobe, a command, an address and a clock, and provide them to the data storage 2003. The memory controller 2002 may provide the data outputted from the data storage 2003, to the host 2001.

The data storage 2003 may include a plurality of memories. The data storage 2003 may receive data, a data strobe, a command, an address and a clock from the memory controller 2002, and perform a write or read operation. Each of the plurality of memories included in the data storage 2003 may include a circuit which corrects an error included in data, by using the error correction code (ECC) scheme.

The error correction circuit included in the host 2001 and the error correction circuits included in the plurality of memories in the data storage 2003 may be realized to operate all together or operate selectively, according to embodiments. The host 2001 and the memory controller 2002 may be realized by the same chip according to an embodiment. The memory controller 2002 and the data storage 2003 may be realized by the same chip according to an embodiment.

While various embodiments have been described above, it will be understood to those skilled in the art that the embodiments described are by way of example only. Accordingly, the semiconductor device and the semiconductor system described herein should not be limited based on the described embodiments.

What is claimed is:

1. A semiconductor system comprising:
a first semiconductor device configured for outputting a transmission command and a transmission address, being inputted with and outputting transmission data, and generating an error flag signal in the case where an error bit is included in the transmission data inputted in a read operation; and
a second semiconductor device configured for storing the transmission address in a lookup table circuit when the error flag signal is enabled, and comparing the transmission address and a storage address stored in the lookup table circuit when the read operation is performed based on the transmission command and outputting the transmission data from the lookup table circuit.

2. The semiconductor system according to claim 1, wherein the second semiconductor device outputs the transmission data from the lookup table circuit when the transmission address and the storage address are the same.

3. The semiconductor system according to claim 1, wherein the second semiconductor device outputs the transmission data from a memory core circuit when the transmission address and the storage address are different.

4. The semiconductor system according to claim 1, wherein the second semiconductor device stores the transmission data in the lookup table circuit when a write operation is performed based on the transmission command and the transmission address and the storage address being the same.

5. The semiconductor system according to claim 1, wherein the second semiconductor device stores the transmission data in the memory core circuit when the write operation is performed based on the transmission command and the transmission address and the storage address not being the same.

6. The semiconductor system according to claim 1, wherein, when a plurality of storage addresses are stored in the lookup table circuit, the second semiconductor device compares the transmission address sequentially with the plurality of storage addresses.

7. The semiconductor system according to claim 1, wherein the first semiconductor device performs an error correction operation for the transmission data, and includes an error correction circuit which generates the error flag signal when an error bit is included in the transmission data.

8. The semiconductor system according to claim 1, wherein the lookup table circuit comprises:
a storage circuit configured for outputting the storage address stored therein, based on a read write command which is generated from the transmission command, storing or outputting first storage data based on the read write command when a control signal has a first logic level, and storing an internal address which is generated from the transmission address, when the error flag signal is enabled; and
a comparison circuit configured for generating the control circuit which has the first logic level when the internal address and the storage address are the same and has a second logic level when the internal address and the storage address are different.

9. The semiconductor system according to claim 8, wherein the second semiconductor device comprises:
a command address input circuit configured for generating the read write command by decoding the transmission command, and generating the internal address by buffering the transmission address;
the memory core circuit configured for storing or outputting second storage data based on the read write command and the internal address when the control signal has the second logic level;
a path selection circuit configured for transferring internal data as the first storage data or transferring the first storage data as the internal data when the control signal has the first logic level, and transferring the internal data as the second storage data or transferring the second storage data as the internal data when the control signal has the second logic level; and
a data input/output circuit configured for outputting the transmission data by buffering the internal data in the read operation, and outputting the internal data by buffering the transmission data in the write operation.

10. A semiconductor device comprising:
a lookup table circuit configured for generating a control signal which has a first logic level when an internal address and a storage address stored therein are the same in a read operation, outputting first storage data stored therein, based on the control signal, and storing the internal address based on an error flag signal;
a path selection circuit configured for transferring the first storage data as first internal data when the control signal has the first logic level; and
an error correction circuit configured for outputting second internal data by correcting an error of the first internal data, and generating the error flag signal when the error of the first internal data occurs.

11. The semiconductor device according to claim 10, wherein the path selection circuit transfers second storage data as the first internal data when the control signal has a second logic level.

12. The semiconductor device according to claim 10, further comprising:
a memory core circuit configured for outputting the second storage data when the control signal has the second logic level.

13. The semiconductor device according to claim 12,
wherein the path selection circuit transfers the first internal data as the first storage data or the second storage data based on the control signal in a write operation,
wherein the lookup table circuit stores the first storage data when the control signal has the first logic level, and
wherein the memory core circuit stores the second storage data when the control signal has the second logic level.

14. The semiconductor device according to claim 10, wherein the lookup table circuit comprises:
a storage circuit configured for outputting the storage address stored therein, in the read operation or the write operation, storing or outputting the first storage data in the case where the control signal has the first logic level, and storing the internal address in the case where the error flag signal is enabled; and
a comparison circuit configured for generating the control circuit which has the first logic level in the case where the internal address and the storage address are the same and has the second logic level in the case where the internal address and the storage address are different.

15. A semiconductor system comprising:
a first semiconductor device configured for outputting a transmission command and a transmission address based on a control signal which is generated by comparing a host address and a storage address stored in a lookup table circuit when a read operation is performed, transferring transmission data or storage data outputted from the lookup table circuit, as internal data, based on the control signal, and storing the host address in the lookup table circuit when the internal data includes an error bit; and
a second semiconductor device configured for storing or outputting the transmission data based on the transmission command and the transmission address.

16. The semiconductor system according to claim 15, wherein the first semiconductor device outputs the storage data from the lookup table circuit when the host address and the storage address are the same, and transfers the storage data as the internal data.

17. The semiconductor system according to claim 15, wherein the first semiconductor device transfers the transmission data as the internal data when the host address and the storage address are different.

18. The semiconductor system according to claim 15, wherein the first semiconductor device transfers the internal data as the storage data or outputs the internal data as the transmission data based on the control signal when a write operation is performed.

19. The semiconductor system according to claim 15, wherein the lookup table circuit comprises:
a storage circuit configured for outputting the storage address stored therein, based on a host command, storing or outputting the storage data based on the host command when the control signal has a first logic level, and storing the host address when the error flag signal is enabled; and
a comparison circuit configured for generating the control circuit which has the first logic level when the host address and the storage address are the same and has a second logic level when the host address and the storage address are different.

20. The semiconductor system according to claim 19, wherein the first semiconductor device comprises:
a path selection circuit configured for transferring the internal data as the storage data or transferring the storage data as the internal data when the control signal has the first logic level, and transferring the internal data as the transmission data or transferring the transmission data as the internal data when the control signal has the second logic level;
an error correction circuit configured for outputting host data by correcting an error of the internal data, and generating the error flag signal when an error bit is included in the internal data; and
a command address output circuit configured for outputting the host command and the host address as the transmission command and the transmission address when the control signal is the second logic level.
